(19) United States
(12) Patent Application Publication
(10) Pub. No.: US 2026/0165159 A1
(43) Pub. Date: Jun. 11, 2026

(54) INTEGRATED CIRCUIT PACKAGE

(71) Applicant: CXMT Corporation, Hefei City (CN)

(72) Inventors: TZUNG-HAN LEE, Hefei City (CN); Xiaoping LIU, Hefei City (CN); CHIH-CHENG LIU, Hefei City (CN)

(73) Assignee: CXMT Corporation, Hefei City (CN)

(21) Appl. No.: 19/439,310

(22) Filed: Jan. 3, 2026

Related U.S. Application Data
(63) Continuation of application No. PCT/CN2025/121465, filed on Sep. 16, 2025.

(30) Foreign Application Priority Data
Dec. 6, 2024 (CN) 202411798666.6

(51) Int. Cl. H10W 70/60; H10B 80/00; H10D 80/30; H10W 70/63; H10W 90/00; H10W 90/10; H10W 90/20; H10W 90/28

(52) U.S. Cl. CPC H10W 70/616; H10W 70/635; H10W 90/10; H10W 90/28; H10W 90/297; H10W 90/722; H10W 90/724; H10B 80/00; H10D 80/30

(57) ABSTRACT

An integrated circuit package, including: a memory chip and a logic chip; and an interface connection structure. The interface connection structure includes a physical layer and conductive pillars connected to the physical layer, the physical layer includes a first physical layer, a second physical layer, and a logical connection layer, the first physical layer is a physical layer of the memory chip, the second physical layer is a physical layer of the logic chip, and both the first physical layer and the second physical layer are connected to the logical connection layer.

### CROSS-REFERENCE TO RELATED APPLICATIONS

This application is a continuation of International Patent Application No. PCT/CN2025/121465, filed on Sep. 16, 2025, which claims priority to Chinese Patent Application No. 202411798666.6, filed on Dec. 6, 2024. The disclosures of the above-referenced applications are hereby incorporated by reference in their entirety.

### TECHNICAL FIELD

Embodiments of the present disclosure relate to the semiconductor field, and in particular, to an integrated circuit package.

### BACKGROUND

In the semiconductor industry, there is a growing demand for a small-sized thin semiconductor apparatus with a high capacity and an electronic product employing the semiconductor apparatus, and therefore, various packaging technologies have emerged. A semiconductor package is disposed to enable an integrated circuit chip to be utilized in the electronic product. The semiconductor package is usually configured so that a semiconductor chip is mounted on a printed circuit board (PCB), and a bonding wire or a bump is utilized to electrically connect the semiconductor chip to the printed circuit board. With development of the electronics industry, an electronic product has a growing demand for high performance, a high speed, and a compact size.

The emergence of a new generation of chips is often accompanied by a new packaging form. A chip packaging technology has undergone several generations of evolution. As the potential of Moore's law becomes exhausted, it has become unsustainable to conventionally improve chip performance through an advanced process technology and solely by increasing a chip area, giving rise to 2.5D and 3D packaging technologies. In the 2.5D/3D packaging technology, multiple chips are present in one package. The multiple chips are integrated and interconnected to manufacture a required chip at more appropriate costs. As a transmission speed of a data signal of the chip increases, a delay and attenuation of the data signal are further caused due to a limitation of a transmission distance between a logic chip and a memory chip.

### SUMMARY

According to some embodiments of the present disclosure, in an aspect of the embodiments of the present disclosure, an integrated circuit package is provided, including:
a memory chip and a logic chip; and
an interface connection structure, where the interface connection structure includes a physical layer and conductive pillars connected to the physical layer, the physical layer includes a first physical layer, a second physical layer, and a logical connection layer, the first physical layer is a physical layer of the memory chip, the second physical layer is a physical layer of the logic chip, and both the first physical layer and the second physical layer are connected to the logical connection layer.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1 is a schematic structural diagram of an integrated circuit package according to an embodiment of the present disclosure;

FIG. 2 is a schematic structural diagram of another integrated circuit package according to an embodiment of the present disclosure;

FIG. 3 is a top view of an integrated circuit package according to an embodiment of the present disclosure;

FIG. 4 is a top view of another integrated circuit package according to an embodiment of the present disclosure;

FIG. 5 is a top view of another integrated circuit package according to an embodiment of the present disclosure; and

FIG. 6 is a schematic structural diagram of another integrated circuit package according to an embodiment of the present disclosure.

### DESCRIPTION OF EMBODIMENTS

The embodiments of the present disclosure are described in detail below with reference to the accompanying drawings. However, it may be understood by a person of ordinary skill in the art that in the embodiments of the present disclosure, many technical details are provided to enable readers to better understand the present disclosure. However, the technical solutions claimed in the present disclosure may be implemented even without these technical details and various variations and modifications made based on the following embodiments.

In the semiconductor industry, with a growing demand for a small-sized thin semiconductor apparatus with a high capacity and an electronic product employing the semiconductor apparatus, development of a packaging technology has become a key to meeting these requirements. The packaging technology not only needs to ensure that an integrated circuit chip can reliably work in an electronic product, but also needs to adapt to a growing demand of the electronic product for high performance, a high speed, and a compact size. A semiconductor package is designed to mount the integrated circuit chip on a PCB, and implement an electrical connection between the chip and the PCB through a bonding wire or a bump. This connection manner ensures that the chip can effectively exchange a signal with an external circuit, and provides necessary physical protection to prevent the chip from being damaged by environmental factors.

With development of the electronics industry, the chip packaging technology has evolved from planar packaging to advanced packaging. As the potential of Moore's law becomes gradually exhausted, a method for solely relying on process scaling to improve chip performance has encountered a bottleneck. Therefore, a 2.5D/3D packaging technology has emerged. Multiple chips are integrated in one package, and an advanced interconnection technology, e.g., a silicon interposer (Si Interposer), is employed to implement high-speed and high-density connections between chips, so that a chip with stronger performance is manufactured at more appropriate costs. In the 2.5D/3D packaging technology, multiple chips are integrated and interconnected to manufacture a required chip at more appropriate costs, and especially in terms of a connection between a logic chip and a memory chip, a signal transmission distance can be significantly shortened, thereby reducing a delay and attenuation of a data signal and improving signal integrity and overall system performance. Although the 2.5D/3D packaging technology brings a significant performance improvement, as a transmission speed of the data signal of the chip increases, problems of the delay and the attenuation of the data signal between the logic chip and the memory chip are still further caused due to a limitation of the transmission distance.

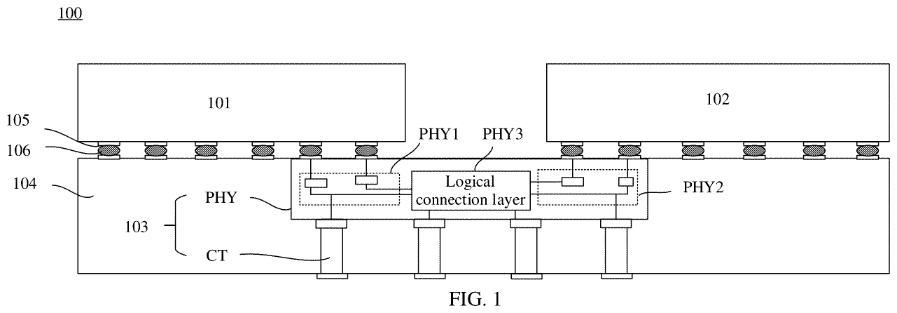

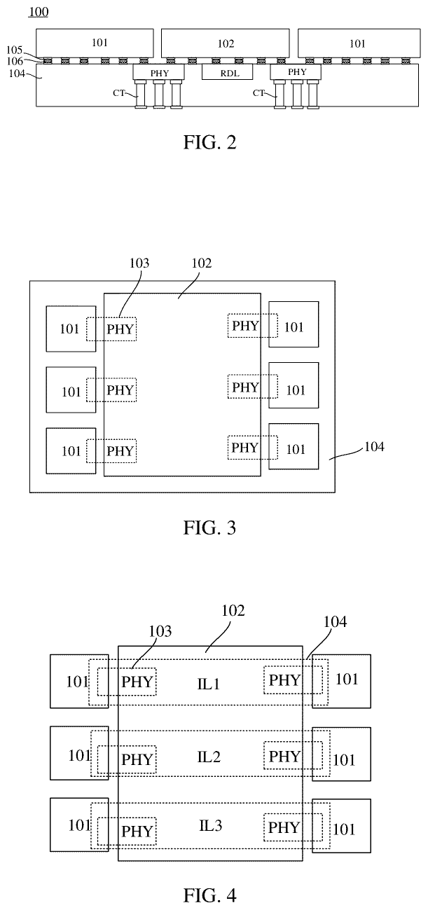

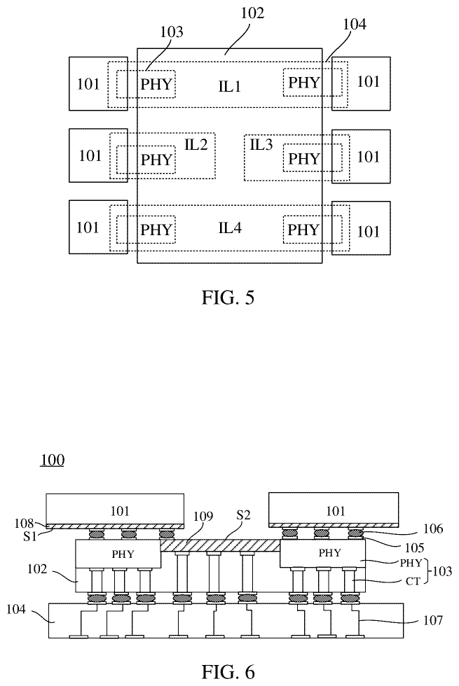

Therefore, to resolve the foregoing problems, the embodiments of the present disclosure provide an integrated circuit package. A semiconductor structure provided in the embodiments of the present disclosure is described below with reference to the accompanying drawings. FIG. 1 is a schematic structural diagram of an integrated circuit package according to an embodiment of the present disclosure. FIG. 2 is a schematic structural diagram of another integrated circuit package according to an embodiment of the present disclosure. FIG. 3 is a top view of an integrated circuit package according to an embodiment of the present disclosure. FIG. 4 is a top view of another integrated circuit package according to an embodiment of the present disclosure. FIG. 5 is a top view of another integrated circuit package according to an embodiment of the present disclosure. FIG. 6 is a schematic structural diagram of another integrated circuit package according to an embodiment of the present disclosure.

An aspect of the embodiments of the present disclosure provides an integrated circuit package 100, including: a memory chip 101 and a logic chip 102; and an interface connection structure 103. The interface connection structure 103 includes a physical layer PHY and conductive pillars CTs connected to the physical layer PHY. The physical layer PHY includes a first physical layer PHY1, a second physical layer PHY2, and a logical connection layer PHY3, the first physical layer PHY1 is a physical layer of the memory chip 101, the second physical layer PHY2 is a physical layer of the logic chip 102, and both the first physical layer PHY1 and the second physical layer PHY2 are connected to the logical connection layer PHY3.

In some embodiments, referring to FIG. 1, the physical layer PHY is configured to connect the memory chip 101 and the logic chip 102 to implement data transmission between the memory chip 101 and the logic chip 102. The interface connection structure 103 further includes the conductive pillars CTs, and the physical layer PHY may output a data signal to the outside or receive a data signal through the conductive pillars CTs. The first physical layer PHY1 and the second physical layer PHY2 respectively correspond to physical layers of the memory chip 101 and the logic chip 102. For example, the first physical layer PHY1 and the second physical layer PHY2 each may include multiple conductive connection wires, or may include a conductive connection wire together with an interconnection layer, to respectively transfer data signals of the memory chip 101 and the logic chip 102 to the first physical layer PHY1 and the second physical layer PHY2. The logical connection layer PHY3 is configured to connect the first physical layer PHY1 and the second physical layer PHY2, to implement transmission, level conversion, and flip-flop functions between the data signals of the first physical layer PHY1 and the second physical layer PHY2. The logical connection layer PHY3 may also include a conductive connection wire or a conductive connection wire and an interconnection layer, to directly connect the first physical layer PHY1 and the second physical layer PHY2 to implement data signal transmission. In addition, the logical connection layer PHY3 may further include a register and a level conversion unit. For example, the register may be a flip-flop, and the flip-flop may include a D flip-flop. The D flip-flop includes a data terminal D and a logic terminal Q. In another embodiment, the flip-flop further includes an RS flip-flop, a JK flip-flop, a T flip-flop, and the like, and may be one or a combination thereof, to implement level conversion or storage of a data signal between the memory chip 101 and the logic chip 102. For example, a material of the conductive connection wire may be copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but is not limited thereto.

The physical layers of the memory chip 101 and the logic chip 102 are integrated into the same interface connection structure 103, so that a signal transmission distance between the logic chip 102 and the memory chip 101 is shortened, and a data signal between the logic chip 102 and the memory chip 101 can be directly transmitted, thereby effectively improving a transmission speed of the data signal. In addition, because the physical layers of the memory chip 101 and the logic chip 102 are integrated into the interface connection structure 103, corresponding physical layers no longer need to be disposed in the memory chip 101 and the logic chip 102, so that a chip area is reduced, and storage density is improved.

In some embodiments, referring to FIG. 1 to FIG. 6, the integrated circuit package further includes an interposer 104. The logic chip 102 is located on the interposer 104. For example, the interposer 104 may be disposed on a package substrate or disposed in the package substrate, is configured to implement interconnection between multiple chips, and may serve as a bridge connecting the chip and the package substrate. The interposer 104 and the package substrate may be connected to each other through a package bump. The interposer 104 may be a silicon interposer (Si interposer) or a redistribution layer interposer (Redistribution Layer Interposer, briefly referred to as “RDL Interposer”). With the interposer 104, a connection trace with a smaller line width and spacing may be formed, so that routing density is improved, thereby meeting a requirement of a high-performance chip. The redistribution layer interposer may further include a redistribution layer RDL. For example, a material of the redistribution layer RDL may be copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but is not limited thereto. In some embodiments, the redistribution layer RDL may be formed by stacking a metal or a metal alloy on a seed layer including titanium, titanium nitride, or titanium tungsten. The interposer 104 may include a non-conductive material made of glass, a semiconductor material (e.g., silicon, GaAs, or InP), or ceramic.

In some embodiments, referring to FIG. 1, the memory chip 101 and the logic chip 102 may be disposed in parallel on the interposer 104, and the interface connection structure 103 is disposed in the interposer 104. The memory chip 101 and the logic chip 102 are connected to each other through the interface connection structure 103 in the interposer 104. It may be understood that a partial region of the interposer 104 may be configured to form the interface connection structure 103, and the memory chip 101 and the logic chip 102 may be interconnected through the interface connection structure 103 located in the interposer 104. For example, the memory chip 101 and the logic chip 102 may be separately bonded to the interposer 104 through multiple bumps 106. Each of the bumps 106 may be disposed on a pad 105, and the bump 106 may be a bump or a C4 bump. A material of the pad 105 and the bump 106 may include a metal, e.g., copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

The interface connection structure 103 is disposed in the interposer 104, so that space utilization of the interposer 104 is improved, and the chip area is reduced. In addition, because the interface connection structure 103 is disposed in the interposer 104, a distance between the memory chip 101 and the logic chip 102 can be further shortened, so that the signal transmission distance between the logic chip 102 and the memory chip 101 is further shortened, thereby effectively improving the transmission speed of the data signal.

In some embodiments, referring to FIG. 3, in a direction parallel to the interposer 104, there are multiple memory chips 101, there are multiple interface connection structures 103, the multiple memory chips 101 and the multiple interface connection structures 103 are disposed around the logic chip 102, and each of the memory chips 101 is connected to the logic chip 102 through a correspondingly connected interface connection structure 103. It may be understood that one logic chip 102 may correspond to multiple memory chips 101, and the multiple memory chips 101 may respectively implement data signal transmission with the logic chip 102 through corresponding interface connection structures 103. The multiple memory chips 101 and the interface connection structures 103 corresponding to the multiple memory chips 101 are disposed, so that while the storage density is improved, a transmission distance between each of the memory chips 101 and the logic chip 102 is effectively shortened, and a transmission speed of a data signal between each of the memory chips 101 and the logic chip 102 is ensured. For example, there are two, four, six, or eight memory chips 101. This is not limited herein.

In some embodiments, in a direction perpendicular to the interposer 104, the memory chip 101 includes multiple vertically stacked high-bandwidth memory chips. For example, each of the memory chips 101 may include multiple vertically stacked high-bandwidth memory (HBM) chips, so that the storage density of the integrated circuit package is effectively improved. For example, each of the HBM chips may include but is not limited to a non-volatile or volatile memory, the volatile memory may include but is not limited to a dynamic random access memory DRAM, and some non-volatile memory types may be block addressable, for example, in a NAND or a NOR technology. Other non-volatile memory types may be byte or block addressable non-volatile memories with a three-dimensional (3-D) intersecting point memory structure, including but not limited to a chalcogenide phase-change material (e.g., chalcogenide glass) hereinafter referred to as “3-D intersecting point memory”. Memories of the non-volatile type may also include another type of byte or block addressable non-volatile memory, including but not limited to a multi-threshold-level NAND flash memory, a NOR flash memory, a single-level or multi-level phase-change memory (PCM), a nanowire memory, a ferroelectric transistor random access memory (FeTRAM), an antiferroelectric memory, a resistive memory (including a metal oxide-based memory, an oxygen vacancy-based memory, and a conductive bridging random access memory (CB-RAM)), a spintronic magnetic junction memory, a magnetic tunnel junction (MTJ) memory, a domain wall (DW), a spin orbit transfer (SOT) memory, a thyristor-based memory, a magnetoresistive random access memory (MRAM) combined with a memristor technology, a spin-transfer torque MRAM (STT-MRAM), or any combination of the foregoing memories.

In some embodiments, referring to FIG. 4 and FIG. 5, the interposer 104 may include multiple integration layers (IL1, IL2, IL3, IL4, . . . , and ILn, where n is an integer greater than or equal to 1), and at least one of the interface connection structures 103 is disposed in one integration layer. For example, the interposer 104 may include multiple integration layers. For example, the integration layers IL1, IL2, and IL3 are spaced apart from each other. Two interface connection structures 103 may be correspondingly disposed in the integration layer IL1, and each of the interface connection structures 103 is correspondingly connected to one memory chip 101. By analogy, two interface connection structures 103 may also be disposed in each of the integration layers IL2 and IL3, and each of the interface connection structures 103 is correspondingly connected to one memory chip 101. In another embodiment, two interface connection structures 103 may be correspondingly disposed in the integration layers IL1 and IL4, and each of the interface connection structures 103 is correspondingly connected to one memory chip 101. One interface connection structure 103 may also be disposed in each of the integration layers IL2 and IL3, and each of the interface connection structures 103 is correspondingly connected to one memory chip. The interposer 104 may alternatively include more integration layers, and each of the interface connection structures 103 is correspondingly connected to one embedding structure. This is not limited herein. The interposer 104 including the multiple integration layers is disposed, different quantities of interface connection structures 103 are disposed in corresponding integration layers, so that the transmission distance between the memory chip 101 and the logic chip 102 is shortened, and an effective area of the interposer 104 is effectively reduced, thereby reducing packaging costs. A material of the integration layer may include a non-conductive material made of glass, a semiconductor material (e.g., silicon, GaAs, or InP), or ceramic.

In some embodiments, referring to FIG. 6, the interposer 104 includes multiple interposer channels 107; the interface connection structure 103 is disposed in the logic chip 102, and the conductive pillars CTs of the interface connection structure 103 are connected to the interposer channels 105 of the interposer 104; and the memory chip 101 is located on the logic chip 102, and the memory chip 101 is connected to the logic chip 102 through the interface connection structure 103 in the logic chip 102. Specifically, the interposer channel 107 may include a metal conductive wire, and is configured to implement data signal transmission between the logic chip 102 and the interposer 104. A material of the metal conductive wire includes but is not limited to copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof. The interface connection structure 103 is disposed in the logic chip 102, and the conductive pillars CTs of the interface connection structure 103 are connected to the interposer channels 105 of the interposer 104. In other words, the interface connection structure 103 may implement data signal input and output through the interposer channel 107. The memory chip 101 is disposed on the logic chip 102. There may be 2, 4, 6, 8, 10, 16, . . . , or 2N memory chips 101, where N is an integer greater than or equal to 1. In another embodiment, there may alternatively be an odd number of memory chips 101. This is not limited herein. For example, two memory chips 101 are disposed on the logic chip 102. The memory chips 101 may be symmetrically distributed on two sides of the logic chip 102, and may be separately connected to the physical layer PHY of the interface connection structure 103 in the logic chip 102 through the bump 106, to implement data signal transmission between the memory chip 101 and the logic chip 102.

The interface connection structure 103 is disposed in the logic chip 102, so that an area of the memory chip 101 is effectively reduced, and the storage density is improved. In addition, the memory chip 101 is located on the logic chip 102, and is directly connected to the interface connection structure 103 in the logic chip 102, so that the data signal transmission distance between the memory chip 101 and the logic chip 102 is further shortened, a signal delay is avoided, and a signal transmission speed is effectively improved.

In some embodiments, referring to FIG. 6, at least one interface connection structure 103 is disposed on the edge of the logic chip 102. The interface connection structure 103 is disposed on the edge of the logic chip 102, so that the memory chip may be disposed on each side of the logic chip 102, thereby increasing memory chips 101 and further improving the storage density.

In some embodiments, still referring to FIG. 6, the memory chip 101 includes a first bonding surface S1, and the first bonding surface S1 includes a first device layer 108; and the logic chip 102 includes a second bonding surface S2, the second bonding surface S2 includes a second device layer 109, and the first device layer 108 and the second device layer 109 are respectively connected to the first physical layer PHY1 and the second physical layer PHY2. The first bonding surface S1 of the memory chip 101 represents a surface bonded to the logic chip 102, the first device layer 108 may be disposed in the first bonding surface S1, and the first device layer 108 may include a transistor, a passive component or an active component, an interconnection layer, and the like. The second bonding surface S2 of the logic chip 102 represents a surface bonded to the memory chip 101, and the second device layer 109 in the second bonding surface S2 may include a logic circuit, e.g., a controller, an input/output interface, a register, or a clock circuit.

In some embodiments, the first bonding surface S1 of the memory chip 101 is bonded to the second bonding surface S2 of the logic chip 102, and a portion of the second device layer 109 of the logic chip 102 is exposed by the memory chip 101. The first bonding surface S1 of the memory chip 101 is bonded to the second bonding surface S2 of the logic chip 102, in other words, it indicates that the memory chip 101 is bonded to the logic chip 102 face to face, so that the transmission distance between the logic chip 102 and the memory chip is significantly shortened, thereby greatly improving the transmission speed of the data signal.

In some embodiments, the physical layer 103 may alternatively be directly disposed as a buried power rail (Buried Power Rails, BPR). The buried power rail BPR may include a buried power rail insulating layer and a rail filling layer, a material of the insulating layer may include silicon nitride, and the rail filling layer may include tungsten W or ruthenium Ru. For example, the buried power rail BPR may be implemented by forming a power rail in the interposer 104 or the logic chip 102. When the physical layer 103 is disposed as the buried power rail BPR, the second bonding surface S2 of the logic chip 102 may be directly bonded to the interposer 104, so that a distance between the logic chip 102 and the interposer 104 is shortened, and a data signal delay between the logic chip 102 and the interposer 104 is avoided.

In some embodiments, the memory chip 101 may be a memory semiconductor chip, and the memory semiconductor chip includes a memory apparatus. For example, the memory apparatus includes a volatile memory apparatus, e.g., a dynamic random access memory (DRAM) or a static random access memory (SRAM). The memory semiconductor chip includes a semiconductor device, and the semiconductor device includes multiple individual components of various types. The multiple individual components include various microelectronic components, e.g., a metal oxide semiconductor field-effect transistor (MOSFET) including a CMOS transistor, a system large-scale integrated circuit (LSI), an active component, or a passive component. The logic chip 102 is not a memory semiconductor chip, but a semiconductor chip configured to perform a logical operation. For example, the logic semiconductor chip may include a logic unit. The logic unit may be differently configured to include multiple circuit elements, including a transistor, a register, and the like. For example, the logic unit may constitute AND (AND), NAND (NAND), OR (OR), NOR (NOR), XOR (exclusive OR), XNOR (exclusive NOR), an inverter (INV), an adder (ADD), a buffer (BUF), a delay element (DLY), a filter (FIL), a multiplexer (MXT/MXIT), OAI (OR-AND-invert), AO (AND-OR), AOI (AND-OR-invert), a D flip-flop, a reset flip-flop, a master/slave flip-flop, a latch, and the like. In addition, for example, the logic unit may alternatively constitute a standard unit executing a desired logical function, e.g., a counter or a buffer. In addition, the logic chip 102 may include or may be an application processor (AP), a microprocessor, a central processing unit (CPU), a controller, or an application-specific integrated circuit (ASIC).

In some embodiments, this application further includes an electronic device, and the electronic device includes the foregoing integrated circuit package 100. Based on different application scenarios, the electronic device or apparatus of the present disclosure may include a server, a cloud server, a server cluster, a data processing apparatus, a robot, a computer, a printer, a scanner, a tablet computer, an intelligent terminal, a PC device, an Internet of things terminal, a mobile terminal, a mobile phone, a dashcam, a navigator, a sensor, a camera lens, a camera, a video camera, a projector, a smartwatch, a headset, mobile storage, a wearable device, a visual terminal, an automated driving terminal, a vehicle, a household appliance, and/or a medical device. The vehicle includes an aircraft, a ship, and/or an automobile. The household appliance includes a television, an air conditioner, a microwave oven, a refrigerator, a rice cooker, a humidifier, a washing machine, a lamp, a gas stove, and a range hood. The medical device includes a magnetic resonance imaging scanner, a B-ultrasound scanner, and/or an electrocardiogram machine. The electronic device or apparatus of the present disclosure may also be applied to the Internet, the Internet of things, a data center, energy, transportation, public management, manufacturing, education, a power grid, telecommunication, finance, retail, a construction site, healthcare, and other fields. Further, the electronic device or apparatus of the present disclosure may be applied to an application scenario related to artificial intelligence, big data, and/or cloud computing, e.g., the cloud, the edge, or a terminal. In one or more embodiments, an electronic device or apparatus with a high computing power according to the solution of the present disclosure may be applied to a cloud device (e.g., a cloud server), and an electronic device or apparatus with low power consumption may be applied to a terminal device and/or an edge device (e.g., a smartphone or a camera lens). In one or more embodiments, hardware information of the cloud device and hardware information of the terminal device and/or the edge device are compatible with each other, so that a suitable hardware resource can be obtained from hardware resources of the cloud device through matching based on the hardware information of the terminal device and/or the edge device, to emulate a hardware resource of the terminal device and/or the edge device, thereby completing unified management, scheduling, and coordination of the terminal and the cloud as a whole or the cloud, the edge, and the terminal as a whole.

According to the embodiments of the present disclosure, the interface connection structure is disposed, and the interface connection structure includes the physical layer and the conductive pillars connected to the physical layer. The physical layer includes the first physical layer, the second physical layer, and the logical connection layer. The first physical layer is a physical layer of the memory chip. The second physical layer is a physical layer of the logic chip. Both the first physical layer and the second physical layer are connected to the logical connection layer. The physical layers of the memory chip and the logic chip are integrated into the same interface connection structure, so that the signal transmission distance between the logic chip and the memory chip is shortened, and the data signal between the logic chip and the memory chip can be directly transmitted, thereby effectively improving the transmission speed of the data signal. Because the physical layers of the memory chip and the logic chip are integrated into the interface connection structure, corresponding physical layers no longer need to be disposed in the memory chip and the logic chip, so that the chip area is reduced, and the storage density is improved.

A person of ordinary skill in the art may understand that the foregoing implementations are specific embodiments for implementing the present disclosure. In an actual application, various modifications may be made to the forms and details of the implementations without departing from the spirit and scope of the embodiments of the present disclosure. Any person skilled in the art may make changes and modifications without departing from the spirit and scope of the embodiments of the present disclosure. Therefore, the protection scope of the embodiments of the present disclosure shall be subject to the scope defined by the claims.

1. An integrated circuit package, comprising:
a memory chip and a logic chip; and
an interface connection structure, the interface connection structure comprising a physical layer and conductive pillars connected to the physical layer, the physical layer comprising a first physical layer, a second physical layer, and a logical connection layer, the first physical layer being a physical layer of the memory chip, the second physical layer being a physical layer of the logic chip, and both the first physical layer and the second physical layer being connected to the logical connection layer.

2. The integrated circuit package according to claim 1, further comprising:
an interposer, the logic chip being located on the interposer.

3. The integrated circuit package according to claim 2, wherein the memory chip and the logic chip are disposed in parallel on the interposer, and the interface connection structure is disposed in the interposer; and
the memory chip and the logic chip are connected to each other through the interface connection structure in the interposer.

4. The integrated circuit package according to claim 3, wherein in a direction parallel to the interposer, there are a plurality of memory chips, there are a plurality of interface connection structures, the plurality of memory chips and the plurality of interface connection structures are disposed around the logic chip, and each of the memory chips is connected to the logic chip through a correspondingly connected interface connection structure.

5. The integrated circuit package according to claim 4, wherein the memory chip comprises a plurality of vertically stacked high-bandwidth memory chips in a direction perpendicular to the interposer.

6. The integrated circuit package according to claim 4, wherein the interposer comprises a plurality of integration layers, and at least one of the interface connection structures is disposed in one of the integration layers.

7. The integrated circuit package according to claim 2, wherein the interposer comprises a plurality of interposer channels;
the interface connection structure is disposed in the logic chip, and the conductive pillars of the interface connection structure are connected to the interposer channels of the interposer; and
the memory chip is located on the logic chip, and the memory chip is connected to the logic chip through the interface connection structure in the logic chip.

8. The integrated circuit package according to claim 7, wherein at least one interface connection structure is disposed on an edge of the logic chip.

9. The integrated circuit package according to claim 7, wherein the memory chip comprises a first bonding surface, and the first bonding surface comprises a first device layer; and the logic chip comprises a second bonding surface, the second bonding surface comprises a second device layer, and the first device layer and the second device layer are respectively connected to the first physical layer and the second physical layer.

10. The integrated circuit package according to claim 9, wherein the first bonding surface of the memory chip is bonded to the second bonding surface of the logic chip, and a portion of the second device layer of the logic chip is exposed by the memory chip.
